(19) United States
(12) Patent Application Publication
(10) Pub. No.: US 2026/0360626 A1
(43) Pub. Date: Nov. 12, 2026

(54) THIN FILM CAPACITOR, MANUFACTURING METHOD THEREFOR, AND ELECTRONIC CIRCUIT BOARD HAVING THE THIN FILM CAPACITOR

(71) Applicant: TDK Corporation, Tokyo (JP)

(72) Inventors: Miyu HASEGAWA, Tokyo (JP); Daiki ISHII, Tokyo (JP); Satoru KAWAI, Tokyo (JP); Mitsuhiro TOMIKAWA, Tokyo (JP)

(21) Appl. No.: 19/135,978

(22) PCT Filed: Dec. 27, 2023
(86) PCT No.: PCT/JP2023/046882

§ 371 Date: Jun. 5, 2025

Related U.S. Application Data
(60) Provisional application No. 63/477,674, filed on Dec. 29, 2022.

(51) Int. Cl. H01G 4/33; H01G 4/008; H01G 4/10; H05K 1/185

(52) U.S. Cl. CPC H01G 4/33; H01G 4/008; H01G 4/10; H05K 1/185; H05K 2201/10015

(57) ABSTRACT

To prevent peeling of a lower electrode in a thin film capacitor using a metal foil having a roughened surface. A thin film capacitor includes a metal foil having a roughened main surface including regions A1 and A2; a dielectric film not covering the region but covering the region; an electrode contacting the metal foil exposed to the region; and an electrode covering the metal foil through the dielectric film provided in the region. A metal material constituting the electrode contacts the metal foil exposed to the region.

### TECHNICAL FIELD

The present disclosure relates to a thin film capacitor and a manufacturing method therefor and, more particularly, to a thin film capacitor using a metal foil and a manufacturing method therefor. The present disclosure also relates to an electronic circuit board having such a thin film capacitor.

### BACKGROUND ART

IC-mounted circuit boards are commonly mounted with a decoupling capacitor so as to stabilize the potential of a power supply for an IC. As the decoupling capacitor, multilayer ceramic chip capacitor is typically used, and a large number of the multilayer ceramic chip capacitors are mounted on the surface of the circuit board to thereby achieve required decoupling capacitance.

In recent years, a mounting space for a large number of multilayer ceramic chip capacitors may sometimes become insufficient due to miniaturization of a circuit board. To cope with this, a thin film capacitor capable of being embedded in a circuit board is sometimes used in place of the multilayer ceramic chip capacitor (see Patent Documents 1 to 4).

Thin film capacitors described in Patent Documents 1 to 4 are constituted by a metal substrate whose surface is roughened and an upper electrode covering the metal substrate surface through a dielectric film. In the Patent Documents 1 to 4, a conductive polymer is taken as an example of the material of the upper electrode.

### CITATION LIST

### Patent Document

[Patent Document 1] International Publication WO 2015/118901

[Patent Document 2] International Publication WO 2018/092722

[Patent Document 3] International Publication WO 2017/026247

[Patent Document 4] International Publication WO 2017/014020

### DISCLOSURE OF THE INVENTION

### Problem to be Solved by the Invention

In thin-film capacitors of such a type, a lower electrode needs to be brought into contact with a metal substrate. If peeling occurs at the interface between the lower electrode and the metal substrate, a connection failure will occur.

The present disclosure describes a technology for preventing peeling of the lower electrode of a thin-film capacitor.

### Means for Solving the Problem

A thin film capacitor according to an aspect of the present disclosure includes: a metal foil having a roughened main surface including first and second regions; a dielectric film covering the second region without covering the first region; a first electrode contacting the metal foil exposed to the first region; and a second electrode covering the metal foil through the dielectric film provided in the second region. A metal material constituting the first electrode contacts the metal foil exposed to the first region.

A thin film capacitor manufacturing method according to an aspect of the present disclosure includes: roughening the main surface of a metal foil, the main surface of a metal foil including first and second regions; forming a dielectric film in the first and second regions; removing the dielectric film covering the first region to expose the metal foil that is positioned in the first region; forming a first electrode on the first region by electrolytic plating performed using the metal foil exposed to the first region as a power feeder; and forming a second electrode on the second region with the dielectric film interposed therebetween.

### Advantageous Effects of the Invention

According to the present disclosure, since the metal material constituting the first electrode is in contact with the roughened surface of the metal foil, it is possible to increase the adhesion between them.

### BRIEF DESCRIPTION OF THE DRAWINGS

FIG. 1 is a schematic cross-sectional view for explaining the structure of a thin film capacitor 1 according to an embodiment of the technology described herein.

FIG. 2 is a partially enlarged view of the electrode E1.

FIG. 3 is a process view for explaining the manufacturing method for the thin film capacitor 1.

FIG. 4 is a process view for explaining the manufacturing method for the thin film capacitor 1.

FIG. 5 is a process view for explaining the manufacturing method for the thin film capacitor 1.

FIG. 6 is a process view for explaining the manufacturing method for the thin film capacitor 1.

FIG. 7 is a process view for explaining the manufacturing method for the thin film capacitor 1.

FIG. 8 is a process view for explaining the manufacturing method for the thin film capacitor 1.

FIG. 9 is a process view for explaining the manufacturing method for the thin film capacitor 1.

FIG. 10 is a process view for explaining the manufacturing method for the thin film capacitor 1.

FIG. 11 is a process view for explaining the manufacturing method for the thin film capacitor 1.

FIG. 12 is a process view for explaining the manufacturing method for the thin film capacitor 1.

FIG. 13 is a schematic cross-sectional view illustrating an electronic circuit board having a configuration in which a thin film capacitor 1 is embedded in a multilayer substrate 100.

FIG. 14 is a schematic cross-sectional view illustrating an electronic circuit board having a configuration in which a thin film capacitor 1 is mounted on the surface of a multi-layer substrate 300.

### MODE FOR CARRYING OUT THE INVENTION

Hereinafter, preferred embodiments of the present invention will be described in detail with reference to the accompanying drawings.

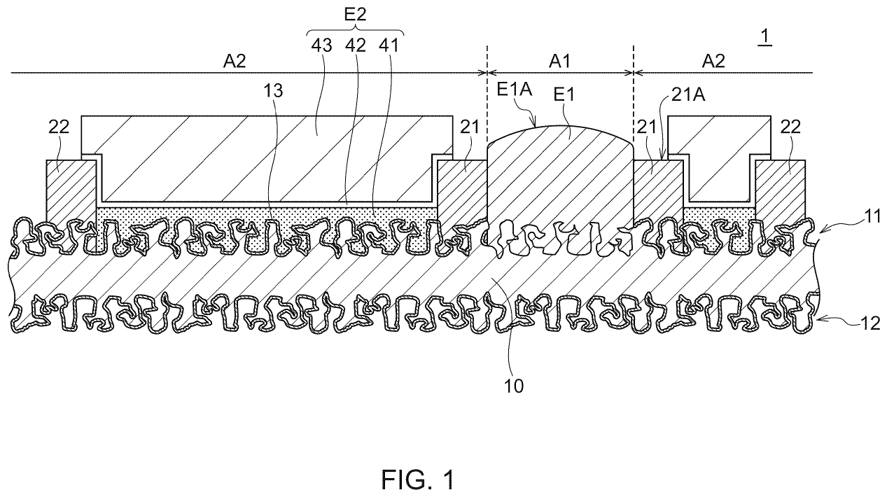

FIG. 1 is a schematic cross-sectional view for explaining the structure of a thin film capacitor 1 according to an embodiment of the technology described herein.

As illustrated in FIG. 1, the thin film capacitor 1 according to the present embodiment includes a metal foil 10 and electrodes El and E2 formed on a main surface 11 as the upper surface of the metal foil 10. The metal foil 10 is made of Al (aluminum), for example. The main surface 11 of the metal foil 10 is roughened. A main surface 12 of the metal foil 10 facing away from the main surface 11 may also be roughened. The center portion of the metal foil 10 in the thickness direction thereof is not roughened. A dielectric film 13 is formed on the roughened main surfaces 11 of the metal foil 10. The dielectric film 13 may also be formed on the main surface 12 as the lower surface of the metal foil 10. The dielectric film 13 may be made of, for example, aluminum oxide.

A ring-shaped or polygonal annular insulating resin 21 and an insulating resin 22 which extends along the outer periphery of the main surface 11 are formed on the main surface 11 of the metal foil 10. The dielectric film 13 is removed in a region Al on the main surface 11 of the metal foil 10 that is surrounded by the insulating resin 21. That is, in the region Al, the roughened main surface 11 of the metal foil 10 is exposed without being covered with the dielectric film 13. In the other region (region A2), the roughened main surface 11 of the metal foil 10 is not exposed but covered with the dielectric film 13. The insulating resin 21 is formed along the boundary between the regions A1 and A2. The surface roughness of the metal foil 10 in the region A1 may be the same as that of the metal foil 10 in the region A2.

The electrode E1 is formed in the region A1 surrounded by the insulating resin 21. The dielectric film 13 may be removed from the entire surface of the region A1 surrounded by the insulating resin 21. The electrode E2 is formed inside the region surrounded by the insulating resin 22, outside the region surrounded by the insulating resin 21. Thus, the electrode E1 contacts the metal foil 10, whereas the electrode E2 is insulated from the metal foil 10 by the dielectric film 13. The electrodes E1 and E2 are insulated from each other by the insulating resin 21, with the result that they function as a pair of capacitance electrodes opposed to each other with the dielectric film 13 interposed therebetween. For example, the electrode E1 constitutes a lower electrode, and the electrode E2 constitutes an upper electrode.

The electrode E1 may protrude from an upper surface 21A of the insulating resin 21 that is parallel to the main surface 11 of the metal foil 10 without contacting the same. This can reduce the planar size of the electrode E1 and facilitates connection between the electrode E1 and an external terminal. The reduction in the size of the electrode E1 allows high-density arrangement of a plurality of the electrodes E1. Further, the electrode E1 does not cover the upper surface 21A of the insulating resin 21, so that it is possible to correspondingly reduce the size of the insulating resin 21, with the result that a larger capacitance can be obtained.

A surface E1A, which is the exposed surface of the electrode E1, may be a convex surface whose height position becomes higher toward its center. This can enlarge the bonding area between the electrode E1 and the external terminal while reducing the planar size of the electrode E1. Further, a stress generated at the interface between the electrode E1 and the external terminal is effectively distributed, thus increasing the bonding strength therebetween. To achieve these effects, the surface E1A of the electrode E1 may be designed such that the difference between the height position at its peripheral edge part and the height position at its center is 2 μm or more.

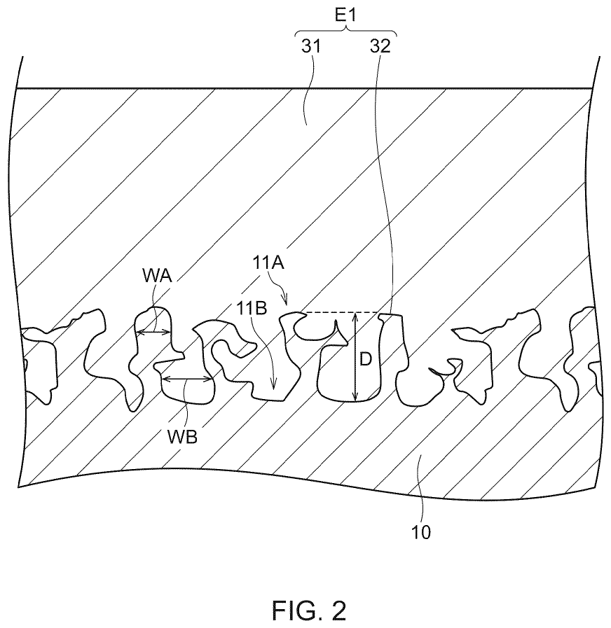

FIG. 2 is a partially enlarged view of the electrode E1.

As illustrated in FIG. 2, the electrode E1 directly contacts the roughened main surface 11 of the metal foil 10. The main surface 11 of the metal foil 10 in the region A1 has a convex part 11A and a concave part 11B. Neither the convex part 11A nor the concave part 11B is covered with the dielectric film 13, and the metal foil 10 is exposed thereto. The difference in height between the convex part 11A and the concave part 11B, i.e., a depth D of the concave part 11B may be 2 μm or more. The depth D may be defined by an average value when the depth D is not constant. When the depth D of the concave part 11B is 2 μm or more, sufficient adhesion between the electrode E1 and the metal foil 10 is achieved. A width WA of the convex part 11A and a width WB of the concave part 11B may fall within the range of 0.1 μm to 2 μm. The widths WA and WB may each be defined by an average value when they are not constant. When the widths WA and WB fall within the range of 0.1 μm to 2 μm, sufficient adhesion between the electrode E1 and the metal foil 10 is achieved.

The electrode E1 includes a body part 31 formed of a good conductor such as Cu (copper) and an interface part 32 contacting the metal foil 10 and formed of, for example, Zn (zinc). The interface part 32 directly contacts the roughened main surface 11 of the metal foil 10. The interface part 32 is formed not only on the surface of the convex part 11A but also on the surface of the concave part 11B. As described above, in the present embodiment, a metal material constituting the electrode E1 directly contacts the roughened main surface 11 of the metal foil 10, so that high adhesion can be achieved between the electrode E1 and the metal foil 10 by anchor effect. In addition, since the entire electrode E1 is formed of a metal material, a reduction in the resistance value of the electrode E1 can be achieved. All the concave parts 11B need not completely be filled with the electrode E1, but a cavity may partially exist in the concave part 11B. Even in this case, 25% or more of a space formed by the concave part 11B is preferably filled with the electrode E1.

The electrode E2 may include a conductive polymer layer 41 that contacts the dielectric film 13 without contacting the metal foil 10, a seed layer 42 provided on the conductive polymer layer 41, and a metal layer 43 provided on the seed layer 42. The material of the metal layer 43 may be a metal material such as copper, nickel, gold, or an alloy thereof. The metal layer 43 may have a structure in which these metal materials are laminated. The material of the seed layer 42 is preferably a material having a barrier function capable of preventing diffusion of copper or the like contained in the metal layer 43, having high adhesion to the metal foil 10 and conductive polymer layer 41, and causing no damage to the conductive polymer layer 41.

The thin film capacitor 1 according to the present embodiment can be used as a decoupling capacitor when being embedded in a multilayer substrate.

The following describes an example of a manufacturing method for the thin film capacitor 1.

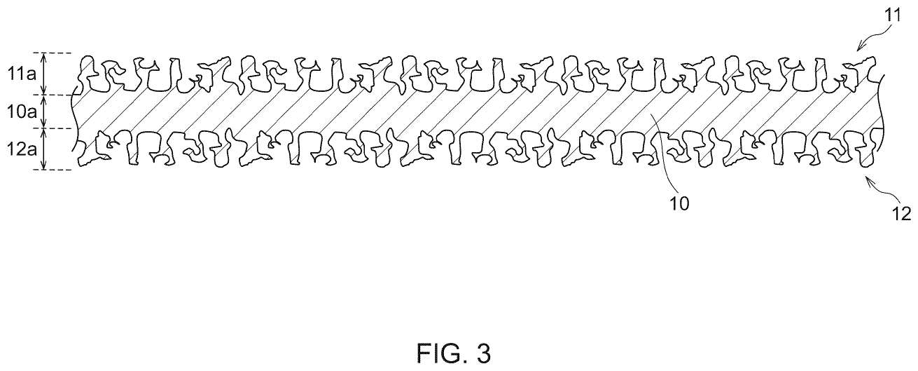

FIGS. 3 to 12 are process views for explaining the manufacturing method for the thin film capacitor 1.

First, the metal foil 10 made of aluminum with a thickness of about 50 μm is prepared, and the main surfaces 11 and 12 are etched for roughening (FIG. 3). In place of roughening the flat metal foil 10, the metal foil 10 may be formed by sintering metal powder. As a result, there are formed, in the metal foil 10, a porous layer 11a positioned on the main surface 11 side and a porous layer 12a positioned on the main surface 12 side. A non-porous layer 10a, which is not subjected to roughening, is positioned between the porous layers 11a and 12a. At this time, it is sufficient to apply roughening to at least the main surface 11 positioned on the upper surface side, and the main surface 12 positioned on the lower surface side may not necessarily be roughened; however, roughening both the main surfaces 11 and 12 can prevent warpage of the metal foil 10. The main surface 11 is preferably etched under a condition that the surface area thereof is increased as much as possible. When both the main surfaces 11 and 12 are roughened, they may be etched under different etching conditions. For example, the main surface 12 may be etched under a condition that adhesion to the multilayer substrate is enhanced as much as possible.

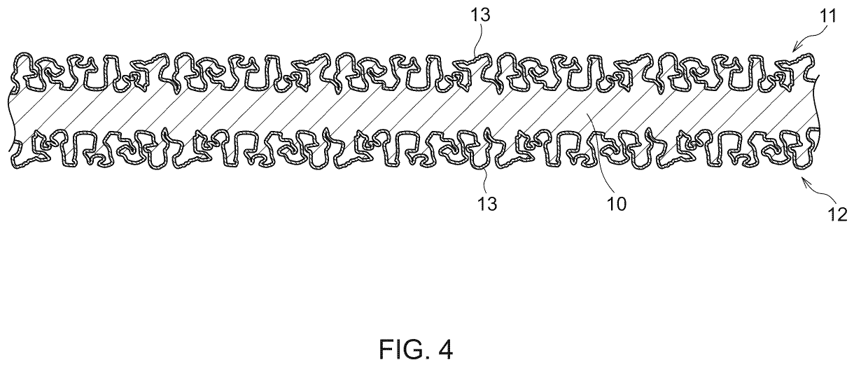

Then, the dielectric film 13 is formed on the surface of the metal foil 10 (FIG. 4). The dielectric film 13 may be formed through oxidation of the metal foil 10 or using a film forming method excellent in coverage performance, such as an ALD method, a CVD method, or a mist CVD method. Examples of the material of the dielectric film 13 include Al₂O₃, TiO₂, Ta₂O₅, and SiNx. Amorphous may be used as the material of the dielectric film 13. In this case, the composition ratio of the dielectric film 13 is not always the same as the composition ratio described above. At this time, it is sufficient to form the dielectric film 13 on at least the main surface 11, and the dielectric film 13 may not necessarily be formed on the main surface 12; however, forming the dielectric film 13 also on the main surface 12 can provide an insulating property to the main surface 12.

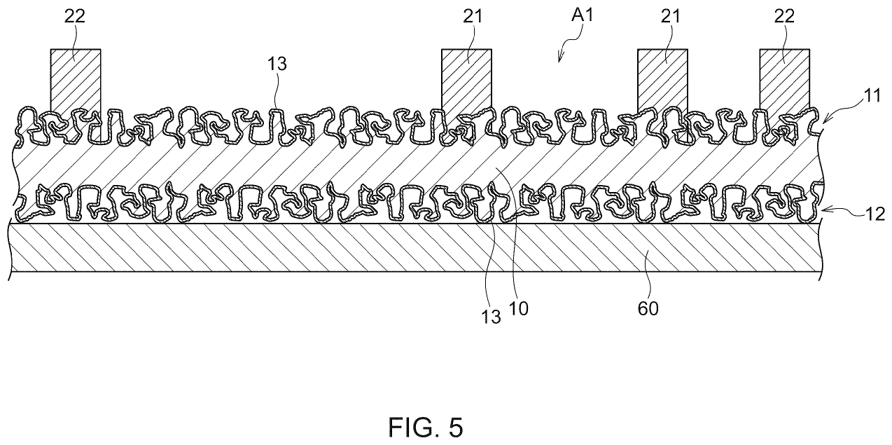

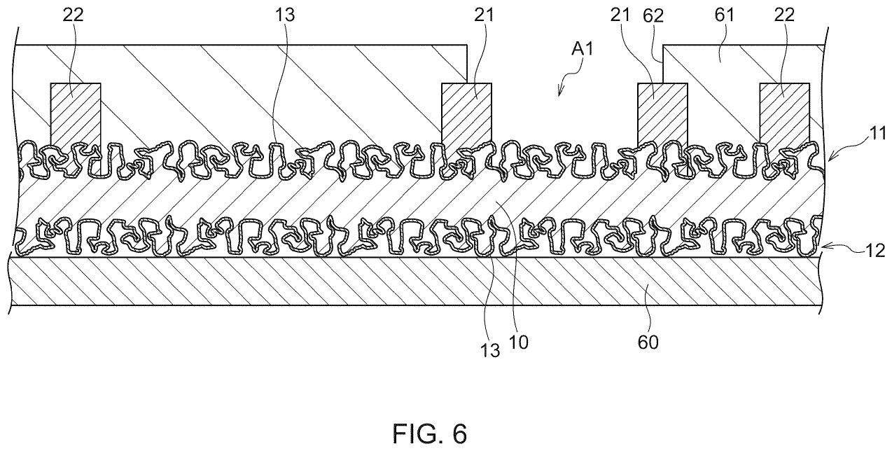

Then, after a support substrate 60 is stuck to the main surface 12 side of the metal foil 10, the insulating resins 21 and 22 are formed on the main surface 11 of the metal foil 10 (FIG. 5). The insulating resins 21 and 22 can be formed using a photolithography patterning method, a screen-printing method, a gravure printing method, an inkjet method, or the like. A part of the main surface 11 of the metal foil 10 that is surrounded by the insulating resin 21 in a plan view constitutes the region A1. Subsequently, a photosensitive resist is formed, followed by exposure and development, to form a patterned resist 61 (FIG. 6). The resist 61 has an opening 62 for exposing the dielectric film 13 on the region A1. The resist may be a positive type or a negative type.

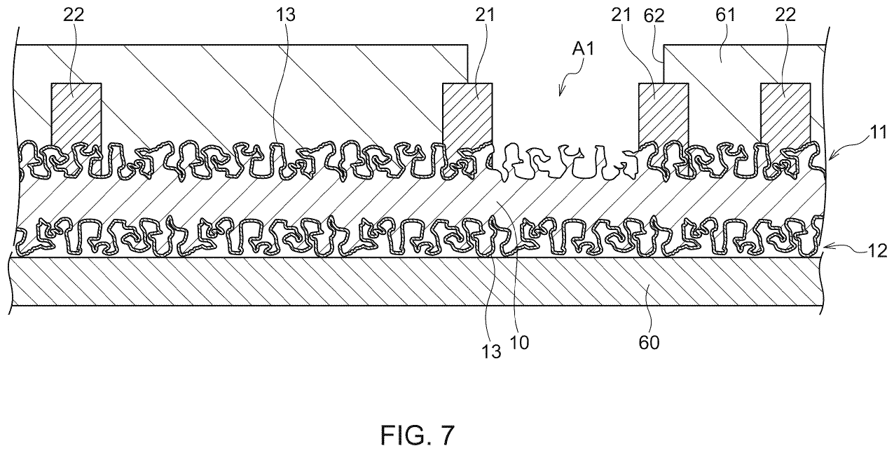

Then, the dielectric film 13 and metal foil 10 that are positioned at the opening 62 of the resist 61 are subjected to zincate treatment. As a result, the dielectric film 13 positioned in the region A1 is removed, and a Zn (zinc) coating is formed on the surface of the metal foil 10 exposed to the region A1 (FIG. 7). Before the zincate treatment, the dielectric film 13 may be subjected to etching. In this case, the dielectric film 13 is etched under a condition that the metal foil 10 is not etched to maintain the roughened state of the region A1. Even when the dielectric film 13 is removed by etching, a natural oxide film is formed on the surface of the metal foil 10 exposed to the region A1. This natural oxide film is removed by the zincate treatment. As a result of the zincate treatment, the dielectric film 13 or the natural oxide film that is positioned in the region A1 is removed, and the exposed main surface 11 of the metal foil 10 is replaced by Zn (zinc).

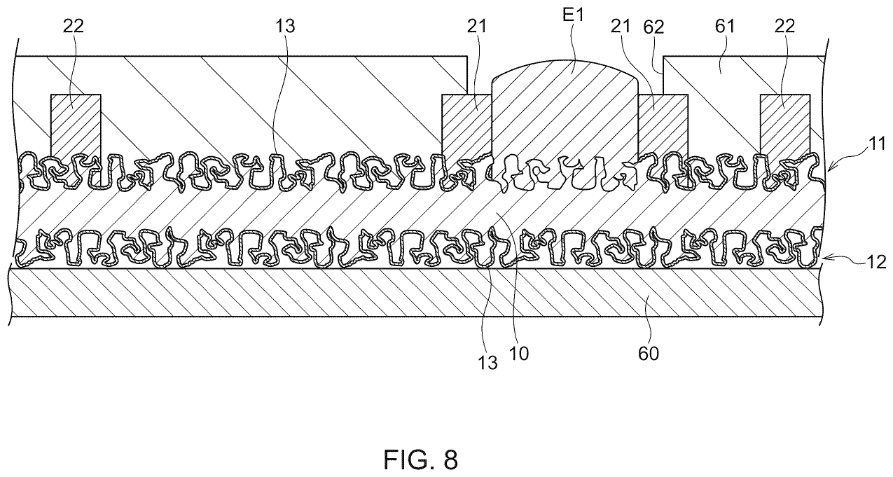

Then, electrolytic plating is performed using the metal foil 10 exposed to the region A1 as a power feeder to form the electrode E1 on the region A1 surrounded by the insulating resin 21 (FIG. 8). The body part 31 of the electrode E1 formed through the above electrolytic plating is formed of, for example, Cu (copper). At the interface between the body part 31 and the metal foil 10, the interface part 32 formed of Zn (zinc) formed through the zincate treatment exists.

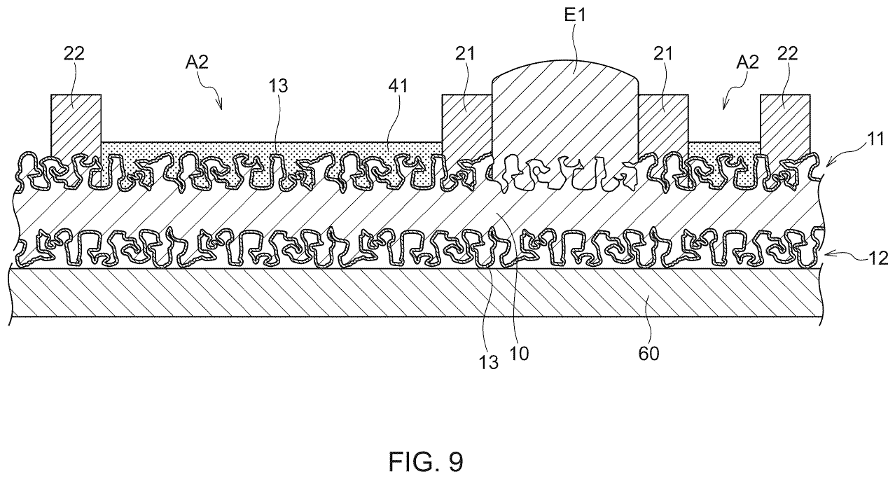

Then, after removal of the resist 61 by ashing or the like, the conductive polymer layer 41 in a paste or liquid form made of a conductive polymer material is formed in the region A2 which is the region inside (i.e., surrounded by) the insulating resin 22, outside the region surrounded by the insulating resin 21 (FIG. 9). The conductive polymer layer 41 is in a paste or liquid form and is thus filled up to the bottom portion of the porous layer 11a due to capillary action. As a result, the conductive polymer layer 41 contacts the dielectric film 13 without contacting the metal foil 10.

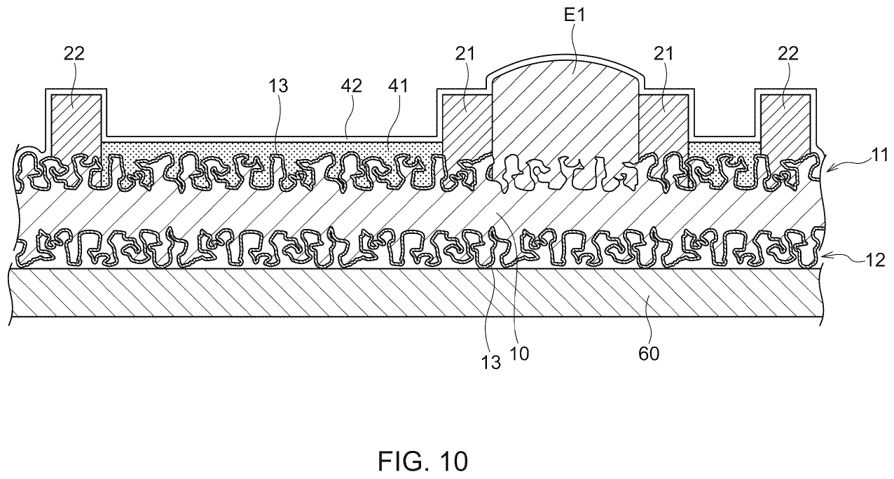

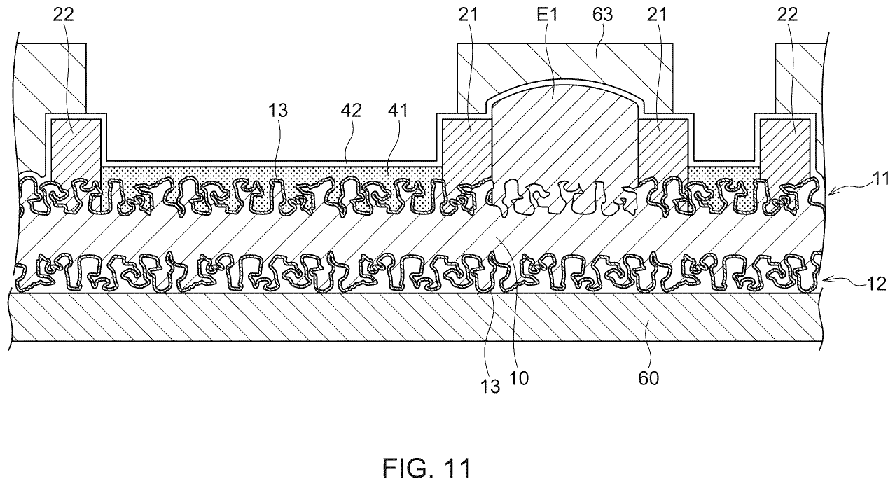

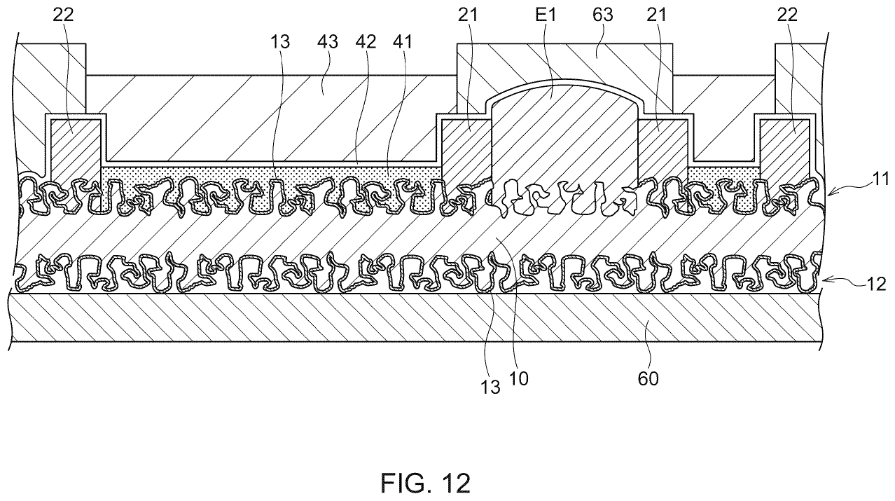

Then, a sputtering method or the like is used to form the seed layer 42 on the entire surface on the main surface 11 side (FIG. 10). Before forming the seed layer 42, a residue remaining on the surface may be removed using a reverse sputtering method or the like. Subsequently, the photosensitive liquid resist 63 is applied on the entire surface, followed by exposure and development, to pattern the resist 63 (FIG. 11). As a result, only a part of the seed layer 42 on which the metal layer 43 is to be formed is exposed. Subsequently, electrolytic plating is performed to form the metal layer 43 (FIG. 12). As a result, the electrode E2 is formed on the region A2 with the dielectric film 13 interposed therebetween.

Then, after removal of the resist 63 by ashing or the like, the exposed part of the seed layer 42 is removed. Subsequently, the support substrate 60 is removed after singulation of the metal foil 10, whereby the thin film capacitor 1 illustrated in FIG. 1 is completed.

The above-described thin film capacitor 1 may be embedded in a multilayer substrate or mounted on the surface of a multilayer substrate.

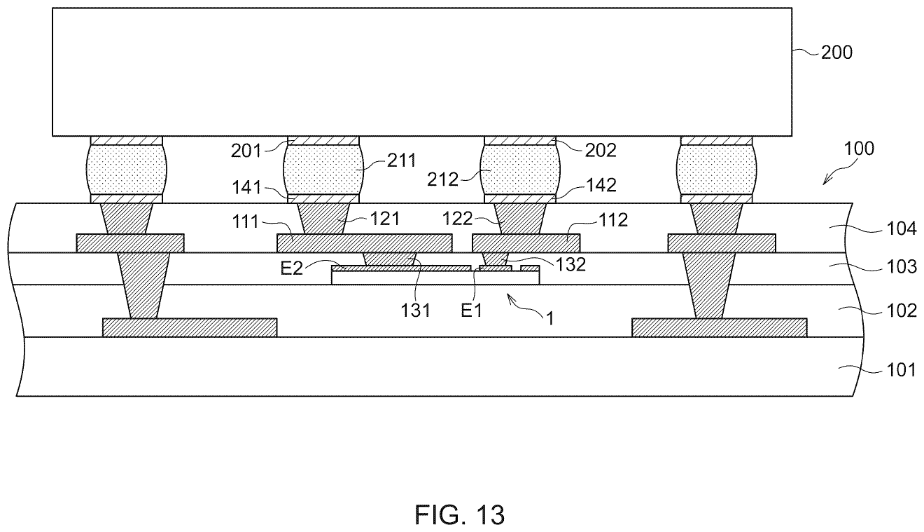

An electronic circuit board illustrated in FIG. 13 has a configuration in which a semiconductor IC 200 is mounted on a multilayer substrate 100. The multilayer substrate 100 includes a plurality of insulating layers including insulating layers 101 to 104 and a plurality of wiring patterns including wiring patterns 111 and 112. The number of the insulating layers is not particularly limited. In the example illustrated in FIG. 13, the thin film capacitor 1 is embedded between the insulating layers 102 and 103. There are provided on the surface of the multilayer substrate 100 a plurality of land patterns including land patterns 141 and 142. The semiconductor IC 200 has a plurality of pad electrodes including pad electrodes 201 and 202. For example, one of the pad electrodes 201 and 202 is a power supply terminal, and the other one thereof is a ground terminal. The pad electrode 201 and land pattern 141 are connected to each other through a solder 211, and pad electrode 202 and land pattern 142 are connected to each other through a solder 212. The land pattern 141 is connected to the electrode E2 of the thin film capacitor 1 through a via conductor 121, the wiring pattern 111, and a via conductor 131. The land pattern 142 is connected to the electrode E1 of the film capacitor 1 through a via conductor 122, the wiring pattern 112, and a via conductor 132. With this configuration, the thin film capacitor 1 functions as a decoupling capacitor for the semiconductor IC 200.

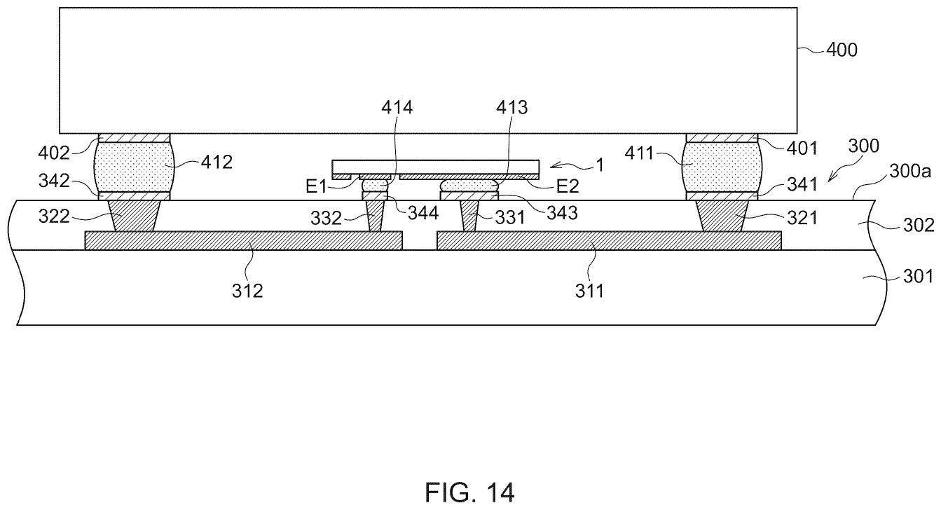

An electronic circuit substrate illustrated in FIG. 14 has a configuration in which a semiconductor IC 400 is mounted on a multilayer substrate 300. The multilayer substrate 300 includes a plurality of insulating layers including insulating layers 301 and 302 and a plurality of wiring patterns including wiring patterns 311 and 312. The number of the insulating layers is not particularly limited. In the example illustrated in FIG. 14, the thin film capacitor 1 is surface-mounted on a surface 300a of the multilayer substrate 300. There are provided on the surface 300a of the multilayer substrate 300 a plurality of land patterns including land patterns 341 to 344. The semiconductor IC 400 has a plurality of pad electrodes including pad electrodes 401 and 402. For example, one of the pad electrodes 401 and 402 is a power supply terminal, and the other one thereof is a ground terminal. The pad electrode 401 and land pattern 341 are connected to each other through a solder 411, and pad electrode 402 and land pattern 342 are connected to each other through a solder 412. The land pattern 341 is connected to the electrode E2 of the thin film capacitor 1 through a via conductor 321, the wiring pattern 311, a via conductor 331, the land pattern 343, and a solder 413. The land pattern 342 is connected to the electrode El of the thin film capacitor 1 through a via conductor 322, the wiring pattern 312, a via conductor 332, the land pattern 344, and a solder 414. With this configuration, the thin film capacitor 1 functions as a decoupling capacitor for the semiconductor IC 400.

While the preferred embodiment of the present disclosure has been described, the present disclosure is not limited to the above embodiment, and various modifications may be made within the scope of the present disclosure, and all such modifications are included in the present disclosure.

The technology according to the present disclosure includes the following configuration examples but not limited thereto.

A thin film capacitor according to an aspect of the present disclosure includes: a metal foil having a roughened main surface including first and second regions; a dielectric film covering the second region without covering the first region; a first electrode contacting the metal foil exposed to the first region; and a second electrode covering the metal foil through the dielectric film provided in the second region. A metal material constituting the first electrode contacts the metal foil exposed to the first region. This enhances adhesion between the first electrode and the metal foil.

The above thin film capacitor may further include an insulating resin which is formed on the main surface of the metal foil along the boundary between the first and second regions, and the first region may be surrounded by the insulating resin. Thus, insulation between the first and second electrodes is achieved by the insulating resin.

In the above thin film capacitor, the dielectric film may be removed from the entire surface of the region surrounded by the insulating resin. This reduces a contact resistance between the first electrode and the metal foil.

In the above thin film capacitor, the first electrode may protrude from the upper surface of the insulating resin that is parallel to the main surface of the metal foil without contacting the upper surface of the insulating resin. This reduces the planar size of the first electrode and insulating resin.

In the above thin film capacitor, the surface roughness of the metal foil in the first region may be the same as a surface roughness of the metal foil in the second region. This further enhances adhesion between the first electrode and the metal foil.

In the above thin film capacitor, the surface of the metal foil in the first region may have a convex part and a concave part. The metal foil may be exposed to the convex part and the concave part without covered with the dielectric film. This reduces a contact resistance between the first electrode and the metal foil.

In the above thin film capacitor, the first electrode may include a body part formed of a first metal material and an interface part contacting the metal foil and formed of a second metal material. This can prevent formation of a natural oxide film on the surface of the metal foil.

In the thin film capacitor, the metal foil may contain AL (aluminum), and the first metal material may contain Cu (copper) , and the second metal material may contain Zn (zinc). This allows the interface part to be formed by zincate treatment.

An electronic circuit board according to an aspect of the present disclosure includes: a substrate having wiring patterns; and a semiconductor IC and the above thin film capacitor provided on the substrate. The first and second electrodes of the thin film capacitor are connected to the semiconductor IC through the wiring patterns. This allows the thin film capacitor to function as a decoupling capacitor for the semiconductor IC.

A thin film capacitor manufacturing method according to an aspect of the present disclosure includes: roughening the main surface of a metal foil, the main surface of a metal foil including first and second regions; forming a dielectric film in the first and second regions; removing the dielectric film covering the first region to expose the metal foil that is positioned in the first region; forming a first electrode on the first region by electrolytic plating performed using the metal foil exposed to the first region as a power feeder; and forming a second electrode on the second region with the dielectric film interposed therebetween. With such an arrangement, the first electrode can be formed directly on the roughened main surface of the metal foil.

In the above manufacturing method, the metal foil may contain AL (aluminum) and may be exposed through zincate treatment. This makes it possible to remove a part of the dielectric film that covers the first region while maintaining the roughened state of the metal foil in the first region.

In the above manufacturing method, a natural oxide film formed on the surface of the metal foil that is positioned in the first region may be removed before forming the first electrode after the metal foil is exposed. This reduces a contact resistance between the first electrode and the metal foil.

### REFERENCE SIGNS LIST

1 thin film capacitor
10 metal foil
10a non-porous layer
11, 12 main surface
11A convex part
11B concave part
11a, 12a porous layer
13 dielectric film
21, 22 insulating resin
21A upper surface
31 body part
32 interface part
41 conductive polymer layer
42 seed layer
43 metal layer
60 support substrate
61 resist
62 opening
63 resist
100 multilayer substrate
101-104 insulating layer
111, 112 wiring pattern
121, 122, 131, 132 via conductor
141, 142 land pattern
200 semiconductor IC
201, 202 pad electrode
211, 212 solder
300 multilayer substrate
300a surface
301, 302 insulating layer
311, 312 wiring pattern
321, 322, 331, 332 via conductor
341-344 land pattern
400 semiconductor IC
401, 402 pad electrode
411-414 solder
A1, A2 region
E1, E2 electrode
E1A surface

1. A thin film capacitor comprising:
a metal foil having a roughened main surface including first and second regions;
a dielectric film covering the second region without covering the first region;
a first electrode contacting the metal foil exposed to the first region; and
a second electrode covering the metal foil through the dielectric film provided in the second region,
wherein a metal material constituting the first electrode contacts the metal foil exposed to the first region.

2. The thin film capacitor as claimed in claim 1, further comprising an insulating resin which is formed on the main surface of the metal foil along a boundary between the first and second regions,
wherein the first region is surrounded by the insulating resin.

3. The thin film capacitor as claimed in claim 2, wherein the dielectric film is removed from an entire surface of a region surrounded by the insulating resin.

4. The thin film capacitor as claimed in claim 2, wherein the first electrode protrudes from an upper surface of the insulating resin that is parallel to the main surface of the metal foil without contacting the upper surface of the insulating resin.

5. The thin film capacitor as claimed in claim 1, wherein a surface roughness of the metal foil in the first region is a same as a surface roughness of the metal foil in the second region.

6. The thin film capacitor as claimed in claim 1,
wherein a surface of the metal foil in the first region has a convex part and a concave part, and
wherein the metal foil is exposed to the convex part and the concave part without covered with the dielectric film.

7. The thin film capacitor as claimed in claim 1, wherein the first electrode includes a body part formed of a first metal material and an interface part contacting the metal foil and formed of a second metal material.

8. The thin film capacitor as claimed in claim 7,
wherein the metal foil contains AL (aluminum),
wherein the first metal material contains Cu (copper), and
wherein the second metal material contains Zn (zinc).

9. A method of manufacturing a thin film capacitor, the method comprising:
roughening a main surface of a metal foil, the main surface of a metal foil including first and second regions;
forming a dielectric film in the first and second regions;
removing the dielectric film covering the first region to expose the metal foil that is positioned in the first region;
forming a first electrode on the first region by electrolytic plating performed using the metal foil exposed to the first region as a power feeder; and
forming a second electrode on the second region with the dielectric film interposed therebetween.

10. The method of manufacturing a thin film capacitor as claimed in claim 9,
wherein the metal foil contains AL (aluminum), and
wherein the exposing the metal foil is performed by a zincate treatment.

11. The method of manufacturing a thin film capacitor as claimed in claim 9, further comprising removing a natural oxide film formed on a surface of the metal foil that is positioned in the first region before forming the first electrode after the metal foil is exposed.

12. An electronic circuit board comprising:
a substrate having wiring patterns; and
a semiconductor IC and the thin film capacitor as claimed in claim 1, provided on the substrate,
wherein the first and second electrodes of the thin film capacitor are connected to the semiconductor IC through the wiring patterns.
